(19) United States
(12) Patent Application Publication
(10) Pub. No.: US 2012/0098075 A1
(43) Pub. Date: Apr. 26, 2012

(54) INTEGRATED ELECTRONIC DEVICE FOR DETECTING MOLECULES AND METHOD OF MANUFACTURE THEREOF

(76) Inventors: Alberto Lamagna, Vicente Lopez (AR); Pedro Marcelo Julián, Bahia Blanca (AR); Pablo Sergio Mandolesi, Bahia Blanca (AR); Alfredo Boselli, Boelogne (AR); Betiana Lerner, Martinez (AR); Maximiliano Sebastián Pérez, Martinez (AR); Pablo Daniel Pareja Obregón, Bahia Blanca (AR)

(21) Appl. No.: 12/910,783

(22) Filed: Oct. 23, 2010

(30) Foreign Application Priority Data
Oct. 23, 2010 (AR) P-09-01-04092

(51) Int. Cl. H01L 29/02; H01L 21/04

(52) U.S. Cl. 257/414; 438/197; 257/E29.002; 257/E21.04

(57) ABSTRACT

An integrated electronic device for detecting gases or biological molecules having a microchip comprising integrated electronics manufactured by the CMOS process. The microchip includes a passivation layer. The passivation layer includes one or more windows configured to cover at least one electronic circuit component of the microchip. The one or more windows leave one or more contacts free. The microchip further includes a sensitive covering coupled with said one or more contacts.

### BACKGROUND OF THE INVENTION

This application claims priority to Argentine Patent Application No. P-09-01-04092, filed Oct. 23, 2010, which is hereby incorporated by reference in its entirety to provide continuity of disclosure.

1. Field of the Invention

Embodiments of the invention described herein pertain to the field of integrated electronic devices. More particularly, but not by way of limitation, one or more embodiments of the invention enable an integrated electronic device for detecting molecules and method of manufacture thereof.

2. Description of the Related Art

There are at present two electronic devices for sensing gases (US 2007/0048181 A1) and biomolecules (US 2007-0178477 A1, US 2007/0158766 A1), most of them using field-effect transistors (FET). These devices use a sensitive coating such as carbon nanotubes, which is deposited between two electrodes. In case of a change in the medium, the sensitive coating changes some of its electrical properties. The change of electrical properties is detected and carried through the gold or aluminum union threads to a higher interface where the data are acquired by an electronic circuit which may have amplifiers, noise filters, etc. Then the signal is processed in this circuit and delivered in graphical form so that the change can be observed in the sensor.

The problem with this type of sensors is that the communication through the union threads may cause faults and be affected by interference from external electromagnetic signals, apart from requiring greater dimensions.

There is a need for an integrated electronic device for detecting molecules and method of manufacture thereof to overcome the problems and limitations described above.

### BRIEF SUMMARY OF THE INVENTION

One or more embodiments of the invention enable an integrated electronic device, or microchip, with sensitive coating for detecting gases or biological molecules, and its manufacturing method.

The application of electronic detection tests with the use of sensitive microchips (SC) is a significant step towards low-cost, low-complexity, high- sensitivity molecular detection.

This electronic device integrates a sensitive coating (e.g. carbon nanotubes, zinc nanotubes, oxide nanotubes (e.g. LaSrMnO4), nanoparticles, or any other sensitive substance) with microchips manufactured by the Complementary Metal Oxide Semiconductor (CMOS) method for the production of SCs.

The proposed invention is useful for detecting all types of biomolecules and gases, depending on the sensitive coating used.

Some examples of detection may be: polynucleotides such as deoxyribonucleic acid (DNA) or ribonucleic acid (RNA), proteins, enzymes, peptides, antibodies, antigens, glucose, tumor cells, bacteria, viruses, nitrogen, oxygen, carbon dioxide, carbon monoxide, etc. The field of application includes, among others, human and animal health, detection of transgenic foodstuffs and detection of gases in the environment and in industrial processes.

The main advantage of the invention is that the device has already incorporated all electronics associated to the acquisition of the data received, so the measurement may be taken and amplified at the inside of the sensor, thus avoiding the interference of external electromagnetic signals. Furthermore, it is possible to carry out an analog to digital conversion inside the same SC, process the data so acquired and have them transmitted to a computer or a portable device with control logics totally incorporated in the chip.

The difference with the existing sensors is that this electronic device has all electronics (amplifiers, noise filters, etc.) integrated within the sensor itself. For this reason, the measurements can be taken and amplified inside the sensor, without any need to take the signals to external amplifiers by means of the gold or aluminum threads, as is the case with the sensors currently in use. Furthermore, both the processing and the communication protocol can be developed in the circuit by incorporating an analog-digital converter. This makes it possible for the CMOS technology to be used for detecting DNA and other biomolecules, as well as for detecting gases. This is a great advantage since the amplification of the signal takes place on the chip itself, increasing the sensitivity and reducing the noises caused by electromagnetic waves present in the environment. These sensors with CMOS technology permit a rapid and precise reading by directly using electrical variables, which facilitates their interaction with circuits integrated within more complex systems. Detection is based on a change of conductance or any other electrical parameter of the sensitive coating every time a macromolecule adheres to it.

Another advantage with respect to the existing FET sensors is that these are manufactured at laboratory scale. The process used for their manufacture is not easily reproducible among laboratories, has a low yield and a very high cost, which does not make it applicable or feasible to be reproduced at industrial scale. The invention's integrated electronic device is manufactured via the CMOS process, the same process that has been in use for years in the computer microprocessor industry. There are a number of companies at worldwide level which offer these manufacturing processes on a commercial scale, which makes it possible to have it manufactured on such scale.

The use of carbon nanotubes in biosensors allows ultrasensitive detection of biological and chemical samples. These sensors permit a quick and precise reading and make direct use of electrical variables, which facilitates their interaction with integrated circuits within more complex systems. Detection is based on a change in the nanotube's conductance at the time a charged macromolecule sticks to receivers or antibodies which have previously been stuck.

When the sensor recognizes a target molecule it issues an electrical signal which, by means of appropriate electronics, results in a clear and simple diagnosis that can be read on a computer screen. Unlike the current systems based on chemical or optical signals which require more time and a greater number of samples, the SC based on electrical signals is faster, obtains results immediately and has a very low cost.

Electronic detection of biomolecules is in an early stage and emerges as an effective alternative to the current detection methods. The commercial methods in existence for current-day analyses include tests with plaquettes, immunological tests, nucleic acid tests based on the polymerase chain reaction (PCR), cultivation on plates, etc. These methods usually require a high level of sample manipulation. The ability to directly and selectively detect individual molecules has potential to make a significant impact on human health, since it may permit a diagnosis in the early stages of an illness.

The advantages of these new SCs also include: small size, low power consumption, ultra-sensitivity and low cost when produced on a large scale.

The object of this invention is a sensing device with electronics integrated to the chip, manufactured by a CMOS process and including a sensitive detection coating.

This integrated electronic device with a sensitive coating includes an SC device with electronics integrated to the chip, which uses a CMOS process. As an innovative element, it includes a window which opens during the manufacturing process to release electrodes, thus permitting the deposit of a sensitive coating around them which provides sensors for detecting biological molecules and gases.

One or more embodiments of the invention enable a method to manufacture an integrated electronic device, or microchip, with sensitive coating for detecting gases or biological molecules, and its manufacturing method.

In one or more embodiments, the method includes forming an N pit. This is usually carried out by means of implantation followed by diffusion. It requires a mask to delimit the position of the pit.

In one or more embodiments, the method includes, after the pit has been created, and after an oxidation process, the active zone is delimited. The chip area where the transistors will be located. The mask used to this effect is called an active zone mask, or “thinox”.

In one or more embodiments, after the active zone has been delimited, gate oxide is created on it by dry oxidation. Then the polysilicon is deposited, usually N+ doped, which will provide the gate to the transistors.

In one or more embodiments, by means of a photolithography stage, with the use of what we will call a polysilicon mask, the transistors' gates are delimited by attacking the polysilicon and the underlying fine oxide everywhere except on those locations indicated by the above-mentioned mask.

In one or more embodiments, the method includes creating by implantation the sources and drains for all transistors. For this a single mask, called the implantation mask, will suffice.

In one or more embodiments, after covering the whole surface with deposited oxide, will include opening holes on the oxide so as to enable the contacts, that is, delimiting the zones where the metal must be in contact with the silicon. A new mask, called the contacts mask, is used for this purpose.

In one or more embodiments, the method includes depositing the metal on the whole chip and eliminated by engraving where it is not needed. This is achieved by means of a last mask, called the metal mask.

In one or more embodiments, the method includes repeating one or more steps in order to obtain successive metal track layers separated by oxide, and contact them wherever so required; thus, if the purpose is to carry out a complex connectioning, two or more metal levels are usually used. To this effect, two additional masks are necessary: a second contacts mask and a second metal mask.

In one or more embodiments, the method includes an upper silicon oxide layer is deposited which protects the whole circuit and makes it passive.

The change of properties that the sensitive coatings undergo when exposed to the substance that must be sensed, may be measured with the use of contacts. A contact includes a conductor element arranged in such a way as to put it in electrical communication with the sensitive coating. It is possible to use at least two contacts located on a defined area so that each contact will be in communication with the sensitive coating. These are called the source and drain contacts. The total number of contacts on an SC may vary between 2 and “N”, where “N” will be as big as allowed by the design and the manufacturing process. An additional conductor element, such as the gate contact, may be provided so that it will not be in electrical communication with the sensitive coating, but there will be electrical capacitance between the gate contact and the sensitive coating. Thus the electrical properties of the sensitive coating can be measured under the influence of a variable or fixed gate voltage.

In the manufacturing process of integrated circuits by means of CMOS technology, a passivation layer is used in order to insulate the chip's electronic components from the environment.

As an innovation, this integrated electronic device shows a design where this passivation stage is not included in the contacts zone through a window on such layer, so the contacts are left available for later deposit of the sensitive coating on them, thus closing the circuit.

Any change of electrical properties sustained by the sensitive coating when exposed to the substance to be detected may provide the basis for the sensor's sensitivity, for example electrical resistance, electrical conductivity, current, voltage, capacitance, impedance, current in the transistor and current outside the transistor, or transistor's voltage threshold.

As a method for recognition of variations in the electrical properties we can include the use of voltage amplifiers, current amplifiers, transconductance amplifiers and transresistance amplifiers. The invention also includes, as an alternative, amplifiers which convert electrical property variations into frequency variations of a periodic signal. This method is particularly sensitive since it permits achieving increased sensitivity by merely enlarging the sampling window as may be desired. Then a signal conditioning filtration permits improving the measured signal. After these amplifications and analog conditionings, it is possible to conduct an analog-digital conversion inside the chip itself and, by means of digital logic, any additional digital filtration or treatment of the signal. Lastly, a digital circuit incorporates the necessary communication protocol so that the chip will directly and autonomously communicate with a computer or any external device to transmit the acquired data and present them graphically to the system's user.

The proposed invention is useful for detecting all types of biomolecules and gases, depending on the sensitive coating incorporated to it. Some examples of detection may be: polynucleotides such as deoxyribonucleic acid (DNA) or ribonucleic acid (RNA), proteins, enzymes, peptides, antibodies, antigens, glucose, tumor cells, bacteria, viruses, nitrogen, oxygen, carbon dioxide, carbon monoxide, etc. Fields of application are, among others, human and animal health, detection of transgenic foodstuffs, and detection of gases in the environment or in industrial processes.

### BRIEF DESCRIPTION OF THE DRAWINGS

The above and other aspects, features and advantages of the invention will be more apparent from the following more particular description thereof, presented in conjunction with the following drawings wherein:

FIG. 1 shows a side view of an integrated electronic device with sensitive coating incorporated to the integrated circuit in accordance with one or more embodiments of an integrated electronic device for detecting molecules and method of manufacture thereof.

FIG. 2 provides a simplified perspective view in perspective of an integrated electronic device with sensitive coating incorporated to the integrated circuit in accordance with one or more embodiments of an integrated electronic device for detecting molecules and method of manufacture thereof.

FIG. 3 is a top view showing a window on the passivation layer of an integrated electronic device in accordance with one or more embodiments of an integrated electronic device for detecting molecules and method of manufacture thereof.

FIG. 4 shows an exemplary configuration in accordance with one or more embodiments of an integrated electronic device for detecting molecules and method of manufacture thereofthe electronic device.

FIG. 5 shows a scheme of the electronic circuits of an integrated electronic device with sensitive coating incorporated to the integrated circuit in accordance with one or more embodiments of an integrated electronic device for detecting molecules and method of manufacture thereof.

### DETAILED DESCRIPTION

An integrated electronic device for detecting molecules and method of manufacture thereof will now be described. In the following exemplary description numerous specific details are set forth in order to provide a more thorough understanding of embodiments of the invention. It will be apparent, however, to an artisan of ordinary skill that the present invention may be practiced without incorporating all aspects of the specific details described herein. In other instances, specific features, quantities, or measurements well known to those of ordinary skill in the art have not been described in detail so as not to obscure the invention. Readers should note that although examples of the invention are set forth herein, the claims, and the full scope of any equivalents, are what define the metes and bounds of the invention.

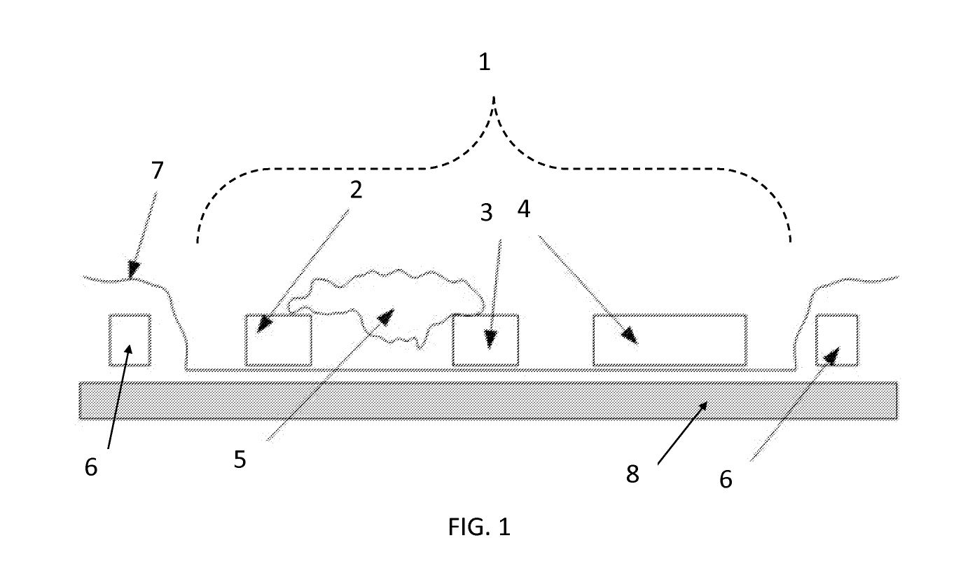

FIG. 1 shows a side view of an integrated electronic device with sensitive coating incorporated to the integrated circuit in accordance with one or more embodiments of an integrated electronic device for detecting molecules and method of manufacture thereof.

The passivation layer 7 shows a window 1 which leaves contacts 2-4 and the sensitive film 5 untouched but covers the circuit's electronic components 6.

These are called “source” contacts (what is commonly known as “source” in electronics) 2 and “drain” contacts, the same name that is usual in electronics 3. They are deposited on a silicon substrate base 8. An additional conductor element, such as the “gate” contact 4, may be provided so that it will not be in electrical communication with the sensitive coating, but ensuring electrical capacitance between the “gate” contact 4 and the sensitive coating 5. Thus the sensitive coating's electrical properties can be measured under the influence of a variable or fixed gate voltage.

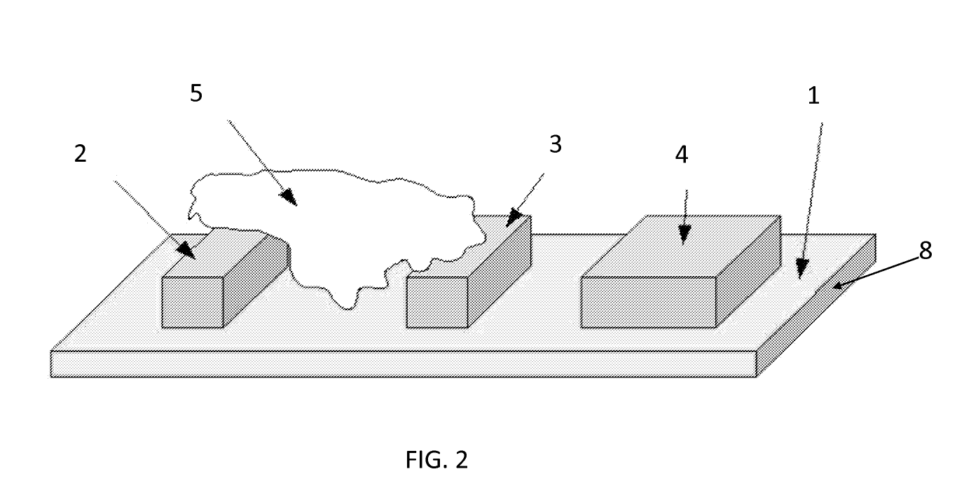

FIG. 2 provides a simplified perspective view in perspective of of an integrated electronic device with sensitive coating incorporated to the integrated circuit in accordance with one or more embodiments of an integrated electronic device for detecting molecules and method of manufacture thereof.

The window components 1 which constitute the sensor and the innovation made possible by this invention, and leave the contacts 2-4 free, thus permitting that a sensitive coating 5 be deposited on them.

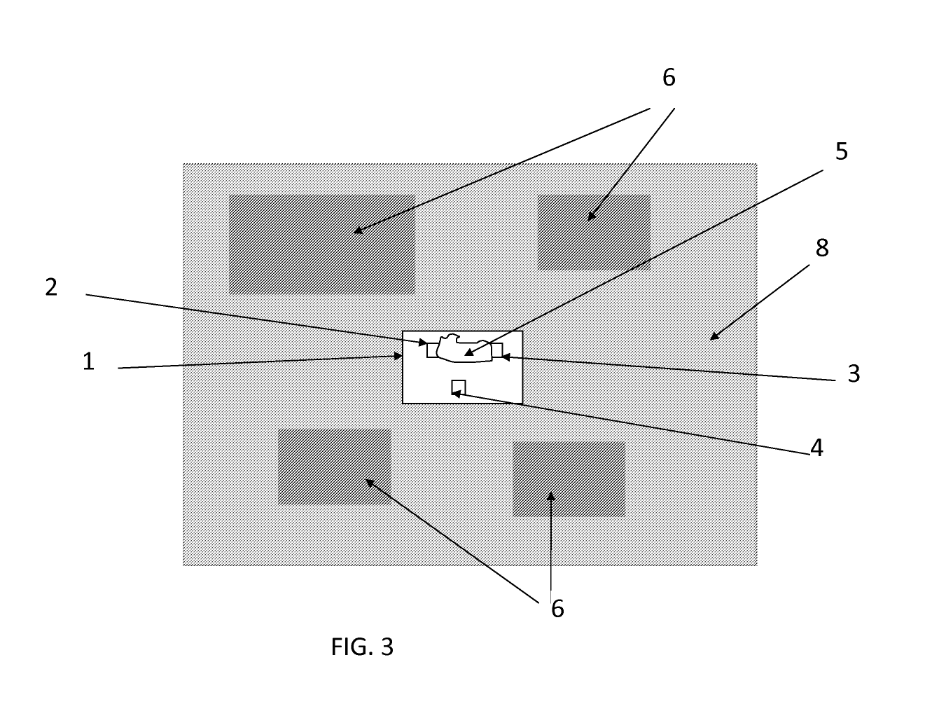

FIG. 3 is a top view showing a window on the passivation layer of an integrated electronic device in accordance with one or more embodiments of an integrated electronic device for detecting molecules and method of manufacture thereof.

The exemplary top view shows an integrated electronic device manufactured with the use of a CMOS procedure, where the window 1 can be appreciated on the passivation layer, leaving the contacts 2-4 free and covering the electronic components of the circuit 6. The sensitive coating 5 and the silicon base 8 are also visible.

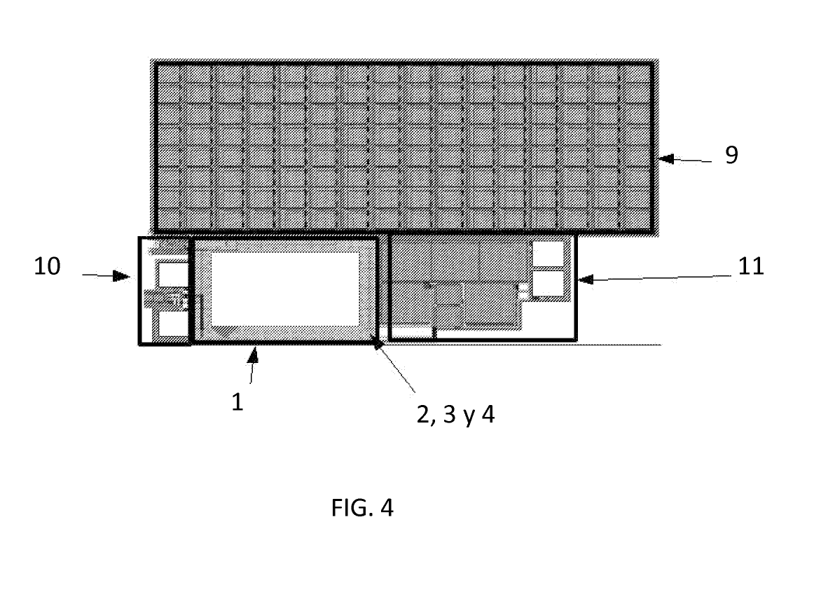

FIG. 4 shows an exemplary configuration in accordance with one or more embodiments of an integrated electronic device for detecting molecules and method of manufacture thereofthe electronic device.

The exemplary configuration shows window 1 and some of the selected design components, which can be used with the help of this technology, such as a voltage amplifier 9, a variable oscillation amplifier 10 and an amplifier based on a polarization current generator 11.

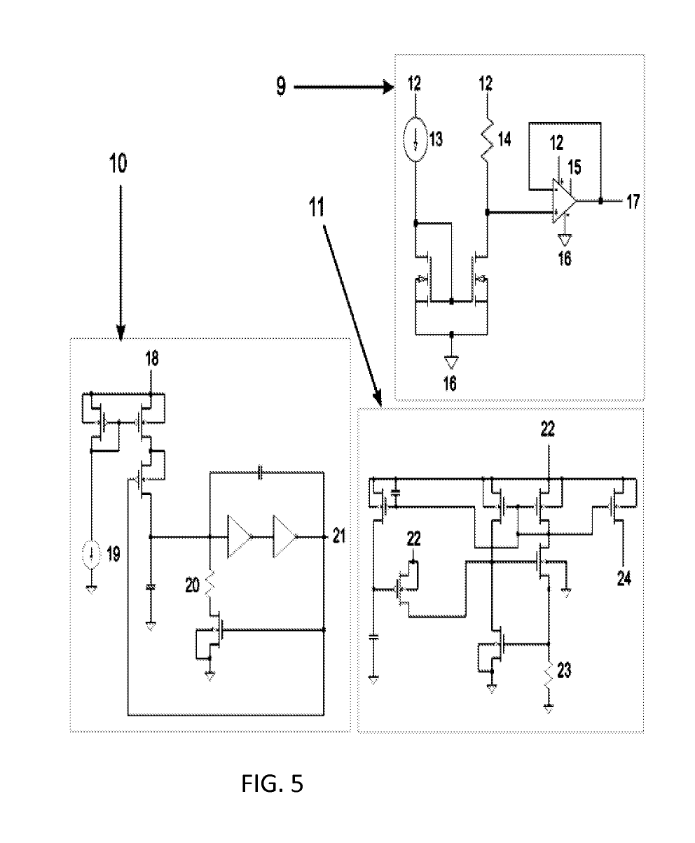

FIG. 5 shows a scheme of the electronic circuits of an integrated electronic device with sensitive coating incorporated to the integrated circuit in accordance with one or more embodiments of an integrated electronic device for detecting molecules and method of manufacture thereof.

A voltage amplifier 9, includes an input voltage 12, a reference current 13, a resistance 14 whose value will be that of the sensitive coating's resistance, a second reference current 15, a ground connection 16 and finally an output voltage 17 which will vary with any change in the sensitive coating's resistance.

A variable oscillation amplifier 10, includes an input voltage 18, a reference current 19, a resistance 20 whose value will be that of the sensitive coating's resistance and finally an output voltage 21 which will vary with any change in the sensitive coating's resistance.

A polarization current generator 11, includes an input voltage 22, a resistance 23 whose value will be that of the sensitive coating's resistance and finally an output voltage 24 which will vary with any change in the sensitive coating's resistance.

In an example of operation of the device, a first electrical signal, such as voltage or current, is measured before the SC's interaction with the sample. A second electrical signal is measured after the SC's interaction with the sample. Correlations can then be established with regard to the changes observed between de device's first and second signals, when the analyte is detected. Other electrical properties which can be measured are: current, conductivity, resistance, inductance, voltage, capacitance, current inside and outside the transistor, natural and forced oscillation frequency of the sample.

The method used for manufacturing the electronic integrated device is the CMOS technique which is well known in the technical environment and comprises the following stages:

Design of masks, contemplating a window for leaving the sensor contacts of interest free and ready for the future implementation of a sensitive coating.

In one or more embodiments, manufacture of the microchip by means of the CMOS process may include the following stages: creation of an N pit, through implantation followed by diffusion; definition of active areas; engraving and filling the desired zones; implantation of regions; deposit and generation of a polysilicon layer pattern; implantation of source and drain regions; deposit and engraving of contacts; deposit of passivation layer: As an innovative characteristic, a region in the area of contacts is released on the passivation layer which will make it possible to deposit the sensitive coating at a late stage; and deposition of a sensitive coating on the contacts related to the window originated in the passivation layer.

The sensitive coating to be used in the SCs may include any substance which shows a change in some electrical property after its interaction with the molecule that we are trying to detect.

The sensor can use different sensitive coatings either separately or with a mixture of them.

The sensitive coatings may be for example tubes or particles of different materials and sizes.

The materials may be for example carbon, zinc, metal oxides and any other substance which shows a change in some electrical property after interacting with the molecule that we wish to detect.

The sizes of the materials forming the sensitive coatings may range from picometers up to millimeters (e.g.: carbon nanotubes). The only limitation is that their size should not exceed the size of the chip.

The sensors' sensitivity and selectivity can be increased by modifying the sensitive coating.

The sensitive coatings can be modified by making them functional with molecules for a specific recognition of the target molecule that we are trying to detect. For example, one form of functionalization is by covalently adsorbing or uniting the sensitive coating with an antibody which can be used for recognizing a specific antigen that we wish to detect. Or a molecule of simple-chain DNA whose sequence hybridizes with a complementary chain whose sequence corresponds to a gen of interest which we wish to detect.

Another type of modification that can be carried out on the sensitive coating for the purpose of increasing its sensitivity is to cause chemical or physical attacks which would leave functional groups more reactive or with a larger surface of contact to permit optimizing the detection process.

A particular example of sensitive coating are the nanotubes. One of their properties is that the electronic flow occurs on the surface and therefore they have a unique sensitivity to environmental disturbances. A nanotube has an electrical resistance characteristic that can be measured by applying a voltage. They can be arranged among the electrodes in a simple way so that only one nanotube will close the circuit between two contacts, and in the form of networks randomly oriented in such a way that several nanotubes will close the circuit between two contacts. A network of nanotubes is a number of nanotubes arranged in a substrate on a defined area containing at least two nanotubes, or several with a sufficiently high density, so that the electrical current will pass through the nanotube network from end to end by means of nanotube-nanotube contact points.

### EXAMPLE 1

### Mask Design

For a better clarification of this invention and of how it can be carried out in real practice, one or more exemplary embodiments of integrated electronic device with sensitive coating for the detection of gases or DNA is provided as follows:

Masks are designed to contemplate a window to leave the sensor contacts free with a view to the future implementation of a sensitive coating. The design of the SC in the example includes four contact arrangements, of which three are associated to different types of amplifiers and one arrangement is for free contacts. The contacts together with their associated amplifiers are called domains. Each arrangement of contacts is connected to a common drain and to sources united by means of metal 1 (aluminum). In the case of the free contacts arrangement, all independent contacts are available for direct connection with the outside of the SC. There is also a floating contact or gate which is common to all contact arrangements and is meant to serve as a voltage reference.

The above-mentioned domains are detailed below:

Domain 1: The interface between the carbon nanotubes and the output signal includes a microelectronic circuit in charge of handling the signals inherent in the measurement, as well as of generating the necessary amplification to obtain an output signal with low noise level. The amplification of domain 1 is carried out by means of a transresistance amplifier circuit. The amplifier circuit includes a current mirror which reflects the input current from one of the pads on the sensitive coating, so as to generate an output voltage. This output voltage is in turn the input to an operational amplifier in unitary gain configuration whose purpose is to act as buffer and prevent the output voltage of the sensitive coating from being charged or affected by any circuit external to the SC. This way, we have an amplifier whose output is proportional to the voltage between terminals of the sensitive coating. As the current circulating by the nanotubes is constant, when the nanotubes' conductance varies a change of voltage is detected at the output. In FIG. 5 we can appreciate the amplifier's electronic scheme 9.

Domain 2: The second amplifier, belonging to domain 2, is a variable oscillator whose oscillation frequency depends on the sensitive coating's conductance value. The variable oscillator's electronic scheme 10 is displayed in FIG. 5. In this case the amplifying circuit includes an ordinary mirror which reflects the input current from one of the pads on a capacitor. As this capacitor acquires charge, a voltage is generated which accesses a pair of serially connected inversion gates. So, once the Vm voltage of the inversion gates is exceeded a change of voltage is generated to allow the activation of an analog switch which disconnects the current sources and connects the sensitive coating. The coating, in turn, discharges the capacitor with a time constant t=RC which will depend on its resistance value.

Once the tension value falls below the above-mentioned Vm value, the inversion gates output changes once again and restarts the cycle. It is thus possible to generate a frequency proportional to the sensitive coating's resistance value. As the substance to be sensed to which the sensitive coating is subjected varies, its resistance to the oscillator also varies and the same occurs with its oscillation frequency.

Domain 3: The third and last domain includes an amplifier based on a polarization current generator. In this case, the amplifying circuit includes a current source whose voltage value of reference is fixed by the resistance value of the sensitive coating and the current circulating through it. This current, in turn, is fed back by a current mirror. Finally, a mirror current source reflects the current at the circuit output, and this can be measured by means of a voltage over a resistance external to the integrated circuit. This way, we obtain a polarization current whose output current depends on the sensitive coating's resistance value. When such resistance varies, a change can be observed in the output polarization current. An electronic scheme of the polarization current generator 11 is shown in FIG. 5.

### EXAMPLE 2

### CMOS Process

After completing the design stage of Example 1, we carried out the manufacture of the device by means of the CMOS process:

An N pit was created through implantation followed by diffusion. This requires a mask to delimit the pit's position.

Once the pit is created and after the ensuing oxidation, it is necessary to delimit the active zone, that is, the chip area where the transistors will be located. The mask in use to this effect is called the active zone mask or “thinox”.

After delimiting the active zone, the gate oxide is grown over it by dry oxidation. Then the polysilicon which will act as the transistors' gate, usually N+ doped, is deposited.

In a photolithographic stage, with use of what we will call the polysilicon mask, the transistors' gates are delimited by attacking the polysilicon and the underlying fine oxide everywhere excepting those locations indicated by the above-mentioned mask.

At this point we proceed to create by implantation the sources and drains for all transistors. To this effect, a single mask, the so-called implantation mask, is sufficient.

The final stages of the process, after covering the whole surface with deposited oxide, will includes opening holes on the latter to make contacts, that is, to delimit the zones where the metal must be in contact with the silicon. A new mask, called the contacts mask, is used for this purpose.

Then the metal is deposited all over the chip and eliminated by engraving where it is not necessary. This is achieved by means of a last mask, called the metal mask.

Lastly, a silicon oxide is deposited on top in order to protect and passivize the whole circuit except for the location of the contacts where the sensitive coating will be deposited.

Once the chip has been manufactured, it is time to carry out the deposit of a sensitive coating on the contacts related to the window originated at the passivation stage. The sensitive coating used varies on the manufactured SCs depending on whether they would be used for detecting gases or for detecting biological molecules.

### EXAMPLE 3

### Gas Sensor Modifications

In the case of a gas sensor, the sensitive coating used may be carbon nanotubes or nanoparticles. In the case of carbon nanotubes, these can be oxidized with a mixture of sulfuric and nitric acid in order to obtain carboxyl groups on their surface and thus make them more sensitive to reaction in the presence of gas molecules. The sensitive coating deposit is carried out through the addition of micro drops on the free area of the passivation layer on the SC. The sensitive coating, in this case nanotubes or nanoparticles, must form a solution or a dispersion without agglomerations. The use of ultrasound can be of help to this effect.

When entering into contact with the nanotubes, the gases may take electrons from (e.g.: nitrogen oxide) or give out electrons (e.g.: ammonia) to the sensitive coating, thus modifying its electrical properties, and this change is detected by the SC.

### EXAMPLE 4

### DNA Sensor Modifications

In the case of the DNA sensor, the sensitive coating may include DNA-functionalized carbon nanotubes or nanoparticles. Detection is based on the hybridization property of the single chain DNA (scDNA) with its complementary single chain DNA (cscDNA) in order to form the double chain DNA (dcDNA).

The SC must use as sensitive coating nanotubes or nanoparticles with sccDNA corresponding to the DNA sequence that we are trying to detect (let us call it, for example, sequence A).

The sample on which the SC must detect whether it has sequence A or not, will be heated in order to separate the dcDNA chains and then deposited on the SC.

If the DNA's sequence A to be detected is present in the sample, then the scDNA of the sample will be hybridized with the sccDNA in union with the SC's nanotubes or nanoparticles in order to produce dcDNA and this hybridization will bring about a change in the electrical behavior of the sensitive coating which can be detected with the SC.

If the DNA's sequence A is not present in the sample, then the sccDNA united to the nanotubes or nanoparticles will remain free and, since there is no hybridization there will be no change in the sensitive coating's electrical behavior so the SC will mark the base measurement level.

There exist multiple methods for preparing the scDNA-covered nanotubes or nanoparticles. One possible form is by mixing the scDNA solution with nanotubes in suspension. The resulting solution contains nanotubes covered with scDNA. The solution is then deposited on the sensor. Another form is to have a nanotube network deposited on the sensor and exposing it to an scDNA solution. When the solution is removed it is observed that the scDNA covers the nanotube. Still another form of linking the scDNA to the nanotubes is by covalent union by means of an amide union. In this case, carboxylic nanotubes and scDNA are used, ending up in an amine group in order to carry out the amide union with the appropriate chemical reagents.

The occurrence, speed and specificity of DNA hybridization will depend on several conditions. The union power of the dcDNA may be increased by astringency techniques. This can be effected through an increase of temperature or a change of buffer, etc. Other astringency controls may include several ionic components in the hybridization medium, such as sodium and magnesium ions. In addition or as an alternative, a voltage may be applied to the sensor elements (for example a nanotube network) before, during and/or after hybridization in order to influence the polynucleotide's behavior. For example, DNA has a phosphate-based skeleton which is typically ionized in the hybridization medium, so it has a localized negative charge. Selectively loaded sensor elements may be used for providing an attraction or repulsion astringency factor. According to the variations in astringency it is possible to distinguish the union of DNA chains with complete or incomplete complementarity.

While the invention herein disclosed has been described by means of specific embodiments and applications thereof, numerous modifications and variations could be made thereto by those skilled in the art without departing from the scope of the invention set forth in the claims.

What is claimed is:

1. An integrated electronic device for detecting gases or biological molecules, comprising:
a microchip comprising integrated electronics manufactured by the CMOS process, wherein said microchip comprises a passivation layer, said passivation layer comprising one or more windows configured to cover at least one electronic circuit component of said microchip, wherein said one or more windows leave one or more contacts free, wherein said microchip further comprises a sensitive coating coupled with said one or more contacts through said one or more windows.

2. The integrated electronic device for detecting gases or biological molecules of claim 1, wherein said one or more contacts comprise at least one source contact and at least one drain contact.

3. The integrated electronic device for detecting gases or biological molecules of claim 2, wherein said one or more contacts comprise at least one gate contact.

4. The integrated electronic device for detecting gases or biological molecules of claim 3, wherein said at least one gate contact is not in electrical communication with said sensitive coating, and wherein electrical capacitance exists between said at least one gate contact and said sensitive coating.

5. The integrated electronic device for detecting gases or biological molecules of claim 4, wherein said sensitive coating comprises a material comprising an electrical property which changes after interacting with a molecule said microchip is configured to detect.

6. The integrated electronic device for detecting gases or biological molecules of claim 5, wherein said sensitive coating comprises a material selected from the group consisting of nanotubes, nanoparticles or carbon, zinc or metallic oxide nanofibers.

7. The integrated electronic device for detecting gases or biological molecules of claim 2, wherein said at least one electronic circuit component comprises a voltage amplifier, a variable oscillation amplifier and an amplifier based on a polarization current generator.

8. The integrated electronic device for detecting gases or biological molecules of claim 2, wherein said at least one electronic circuit component is configured to determine at least one resistance related to the sensitive coating, wherein said at least one resistance influences an output current value corresponding to a level of a molecule for measurement or detection.

9. The integrated electronic device for detecting gases or biological molecules of claim 5, wherein said molecule is a biological molecule.

10. The integrated electronic device for detecting gases or biological molecules of claim 9, wherein said molecule is selected from the group consisting of polynucleotides, deoxyribonucleic acid (DNA), ribonucleic acid (RNA), proteins, enzymes, peptides, antibodies, antigens, glucose, tumor cells, bacteria, and viruses.

11. The integrated electronic device for detecting gases or biological molecules of claim 5, wherein said molecule is a gas.

12. The integrated electronic device for detecting gases or biological molecules of claim 11, wherein said molecule is selected from the group consisting of nitrogen, oxygen, carbon dioxide, and carbon monoxide.

13. A method for manufacturing an integrated electronic device for detecting gases or biological molecules, comprising the steps of:
obtaining a mask configured to generate one or more windows configured to leave one or more sensor contacts of a microchip exposed;
obtaining said microchip, wherein said microchip is manufactured by a CMOS method, said microchip comprising said one or more sensor contacts;
applying a passivation layer to a surface of said microship using said mask;
releasing one or more regions of said passivation layer corresponding to said one or more windows to expose said one or more sensor contacts;
depositing of a sensitive coating on said contacts exposed by said one or more windows of said passivation layer.

14. The method for manufacturing an integrated electronic device for detecting gases or biological molecules of claim 13, wherein said microchip is configured to detect one or more gasses, and wherein said step of depositing said sensitive coating comprises depositing a substance that undergoes changes in its electrical properties when it comes into contact with gasses.

15. The method for manufacturing an integrated electronic device for detecting gases or biological molecules of claim 14, wherein said substance is selected from the group consisting of carbon nanotubes and nanoparticles.

15. The method for manufacturing an integrated electronic device for detecting gases or biological molecules of claim 13, wherein said microchip is configured to detect one or more biological molecules, and wherein said sensitive coating is selected from the group consisting of DNA-functionalized carbon nanotubes and DNA-functionalized nanoparticles.

16. A method for manufacturing an integrated electronic device for detecting gases or biological molecules, comprising the steps of: creating an N pit through implantation followed by diffusion;
defining one or more active areas;
engraving and filling one or more desired zones;
implanting of one or more regions;
depositing and generation of a polysilicon layer pattern;
implantation of one or more sources and one or more drains;
depositing and engraving of one or more contacts, wherein at least one contact is associated with said one or more sources and said one or more drains;
depositing a passivation layer and releasing one or more window regions to expose one said one or more contacts ; and
depositing a sensitive coating on said one or more contacts related to said one or more window regions in said passivation layer.
